(19) United States
(12) Patent Application Publication
(10) Pub. No.: US 2018/0157360 A1
(43) Pub. Date: Jun. 7, 2018

(54) TOUCH PANEL AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Zhiyang Gao, Beijing (CN); Xianjie Shao, Beijing (CN); Jing Lv, Beijing (CN); Yimin Chen, Beijing (CN); Zhaozhe Xu, Beijing (CN)

(21) Appl. No.: 15/705,072

(22) Filed: Sep. 14, 2017

(30) Foreign Application Priority Data
Dec. 1, 2016 (CN) 201611091121.7

(51) Int. Cl. G06F 3/041; G06F 3/044

(52) U.S. Cl. CPC G06F 3/0412; H01L 27/323; G06F 3/044

(57) ABSTRACT

A touch panel is disclosed. The touch panel includes: a display panel comprising a plurality of pixel regions, each pixel region having a shape of a parallelogram; and a touch sensitive layer comprising a plurality of touch control electrodes corresponding to the plurality of pixel regions respectively, each touch control electrode comprising a plurality of electrode strips arranged parallel to and spaced apart from each other. An extension direction of the electrode strips of each touch control electrode is parallel to or perpendicular to a direction of a long side of the parallelogram of a pixel region corresponding to the touch control electrode. A display device including the touch panel is also disclosed.

### CROSS-REFERENCE TO RELATED APPLICATION

This application claims the benefits of Chinese Patent Application No. 201611091121.7 filed on Dec. 1, 2016 in the State Intellectual Property Office of China, the whole disclosure of which is incorporated herein by reference.

### TECHNICAL FIELD

Embodiments of the present disclosure generally relate to the field of display technologies, and specifically, to a touch panel and a display device having the touch panel.

### BACKGROUND

Touch control technologies have been widely used in various display devices, including organic electroluminescent display panels. As compared with conventional display panels that only provide a display function, a display panel having a touch control function may enable information interactions between a user and a control device for controlling the display panel. Therefore, a touch control display panel may completely or partially replace a conventional input device, such that existing display panels can not only display images but also can be touch controlled.

In a currently used capacitive type touch control display panel, on one hand, touch control electrodes are usually arranged periodically, and on the other hand, pixels within an organic electroluminescent display panel are arranged periodically. Thus, in the capacitive type organic electroluminescent display panel, a periodic pattern of the touch control electrodes and a periodic pattern of the pixel regions will be superimposed, and Moiré fringes will be easily generated, and display effect of the display panel will be adversely affected.

### SUMMARY

The present invention has been made to overcome or alleviate at least one aspect of the above mentioned and other disadvantages.

Therefore, an aspect of the present disclosure is to provide a touch panel.

According to an exemplary embodiment, the touch panel may comprise: a display panel comprising a plurality of pixel regions, each pixel region having a shape of a parallelogram; and a touch sensitive layer comprising a plurality of touch control electrodes corresponding to the plurality of pixel regions respectively, each touch control electrode comprising a plurality of electrode strips arranged parallel to and spaced apart from each other. An extension direction of the electrode strips of each touch control electrode is parallel to or perpendicular to a direction of a long side of the parallelogram of a pixel region corresponding to the touch control electrode.

According to another exemplary embodiment, the display panel may include an organic electroluminescent diode display panel.

According to a further exemplary embodiment, the pixel region and the touch control electrode may have the same shape.

According to a still further exemplary embodiment, the shape of the pixel region may be a rhombus or rectangle.

According to a still further exemplary embodiment, a shape of the touch control electrode may be a rhombus or rectangle.

According to a still further exemplary embodiment, the pixel regions may be arranged into an array.

According to a still further exemplary embodiment, the touch control electrodes may be arranged into an array.

According to a still further exemplary embodiment, a material of the touch control electrode comprises any one of indium tin oxide, indium zinc oxide and indium gallium tin oxide.

Another aspect of the present disclosure is to provide a display device.

In an exemplary embodiment, the display device may comprise the touch panel according to any one of the above embodiments.

### BRIEF DESCRIPTION OF THE DRAWINGS

The above and other features of the present disclosure will become more apparent by describing in detail exemplary embodiments thereof with reference to the accompanying drawings, in which:

FIG. 1 is an illustrative drawing showing a structure of a touch panel according to an exemplary embodiment of the present disclosure;

FIG. 2 is an illustrative drawing showing a pixel region and a touch control electrode of the touch panel shown in FIG. 1, and showing an orientation of electrode strips;

FIG. 3 is an illustrative drawing showing an orientation of electrode strips according to an alternative embodiment of FIG. 2;

FIG. 4 is an illustrative drawing showing a structure of a touch panel according to another embodiment of the present disclosure;

FIG. 5 is an illustrative drawing showing a pixel region and a touch control electrode of the touch panel shown in FIG. 4, and showing an orientation of electrode strips; and

FIG. 6 is an illustrative drawing showing an orientation of electrode strips according to an alternative embodiment of FIG. 5.

### DETAILED DESCRIPTION OF EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

According to an aspect of the present disclosure, there is provided a touch panel. FIG. 1 is an illustrative drawing showing a structure of a touch panel according to an embodiment of the present disclosure. As shown in FIG. 1, the touch panel comprises a display panel and a touch sensitive layer. The display panel comprises a plurality of pixel regions 10 arranged into an array, and each pixel region has a shape of a parallelogram. The touch sensitive layer comprises a plurality of touch control electrodes 20 arranged into an array, and each touch control electrode 20 comprises a plurality of electrode strips 21 disposed in parallel to and spaced apart from each other. An extension direction of the touch control electrodes 20 in each of the electrode strips 21 is parallel to or perpendicular to a direction of a long side of the parallelogram.

It is noted that, generally, a pixel region 10 means a region of the display panel within which pixel units are arranged, and usually, each pixel unit comprise a thin film transistors, a light emitting component and the like. The light emitting component may be an organic electroluminescent diode.

Usually, respective pixel regions 10 have the same shape and size, and respective touch control electrodes 20 also have the same shape and size. A pattern of the pixel region 10 may be regarded as an amplitude grating, a light transmissive zone thereof is a bright zone and a light-shielding zone thereof is a dark zone. A pattern of the touch control electrode 20 may be regarded as a phase grating, and there is a phase difference between a position of an electrode strip 21 and a position where no the electrode strip 21 is located. When light emitted from the amplitude grating passes through the phase grating, grating diffraction occurs. It is considered that a new grating is formed when the amplitude grating and the phase grating are superimposed. The shorter the period of the new grating is, the lower the possibility of human's eyes recognizing the period of the new grating. Generally, human's eyes can hardly recognize a period smaller than 200 μm. In the touch panel of the present embodiment, since the extension direction of the electrode strips 21 is in parallel to or perpendicular to the direction of the long side of the pixel region 10, the period of the new grating formed after the superimposition can be minimized. The possibility of Moiré fringes being recognized by human's eyes is lowered, and display effect of the touch panel becomes better.

In a preferable embodiment, the display panel in the present disclosure is an organic electroluminescent diode display panel.

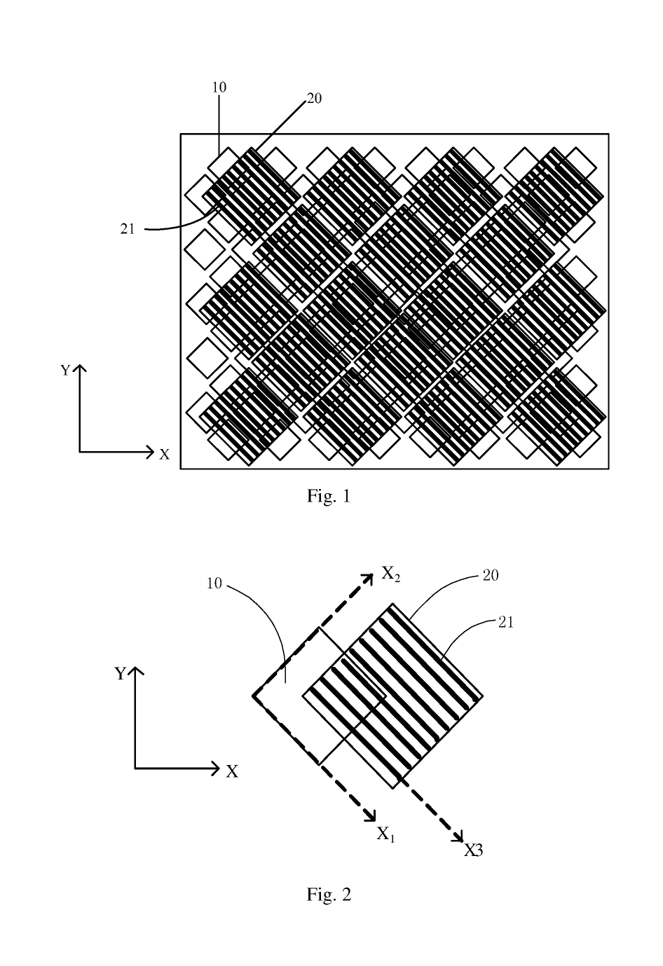

As a specific example of the present embodiment, as shown in FIGS. 1 and 2, the display panel of the touch panel comprises a plurality of square pixel regions 10 arranged into an array. Specifically, as shown in FIG. 1, the plurality of pixel regions 10 are arranged in a X direction and a Y direction perpendicular to the X direction. As shown in FIG. 2, given that an included angle between an extension direction X₁ of a side of the square of each pixel region 10 and the direction X is 45° (or, an included angle between an extension direction X₂ of another side of the square of each pixel region 10 and the direction Y is 45°), then an included angle between the extension direction X₃ of the electrode strips 21 of each touch control electrode 20 and the direction X is 45°. In this case, the extension direction X₃ of the electrode strips 21 is parallel to the direction X₁ in which a minimum width of each pixel region 10 extends (or, the extension direction X₃ of the electrode strips 21 is perpendicular to the direction X₂ in which another minimum width of each pixel region 10 extends).

In a case of an arrangement period of the pixel regions in each of the X and Y directions being 303 μm, it is determined through experiments that, with the structure or configuration provided in the above embodiment, a level of Moiré fringes is about Level 0.5, while in an existing touch panel, a level of Moiré fringe is about Level 3 to 4. In other words, the structure or configuration provided by the present embodiment can effectively constrain or eliminate Moiré fringes.

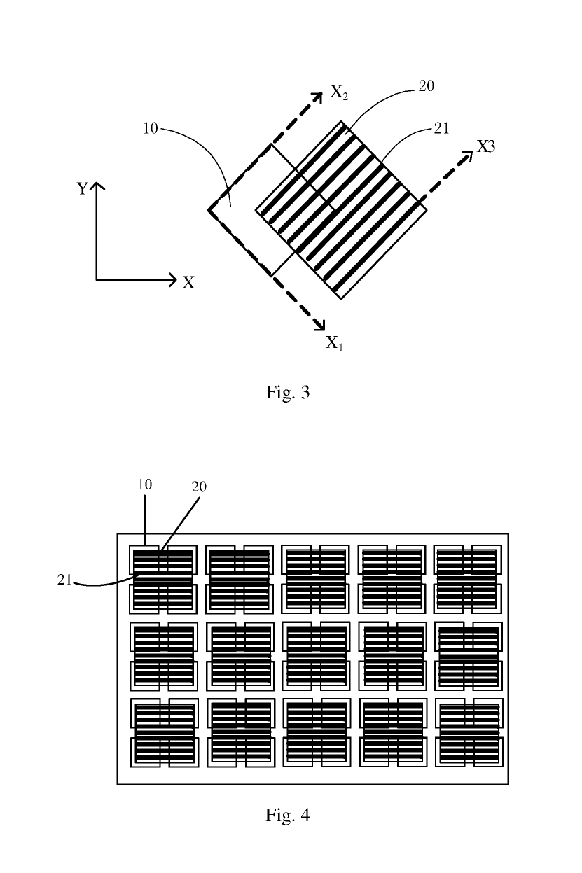

In an alternative embodiment shown in FIG. 3, the extension direction X₃ of the electrode strips 21 is perpendicular to the direction X₁ in which a minimum width of each pixel region 10 extends (in other words, the extension direction X₃ of the electrode strips 21 is parallel to the direction X₂ in which another minimum width of each pixel region 10 extends).

Besides the embodiments described above, the shape of each pixel region may also be a rectangle or a rhombus. A square may be regarded as a special rectangle or rhombus. Also, a square, rectangle or rhombus may be regarded as a special parallelogram. In a condition of the shape of the pixel region being a rectangle, the extension direction of the electrode strips 21 is parallel to or perpendicular to an extension direction of a long side of the rectangle. In a condition of the shape of the pixel region being a rhombus, since four sides of the rhombus have the same length, the extension direction of the electrode strips 21 is parallel to or perpendicular to an extension direction of any side of the rhombus.

FIGS. 4 and 5 show another embodiment according to the present disclosure, and the only differences between the embodiment shown in FIGS. 4 and 5 and the embodiment shown in FIG. 1 lie in the correspondence between the pixel regions and the touch control electrodes, and orientations of the pixel regions and orientations of the touch control electrodes. As shown in FIGS. 4 and 5, directions X₁ and Y₁ in which minimum widths of each square pixel region 10 extend respectively coincide with the directions X and Y respectively, and the extension direction of the electrode strips 21 of the touch control electrode 20 coincides with the direction X. With such arrangement, technical effects similar to those of the embodiment shown in FIG. 1 can be obtained, and in other words, Moiré fringes can be effectively constrained or eliminated.

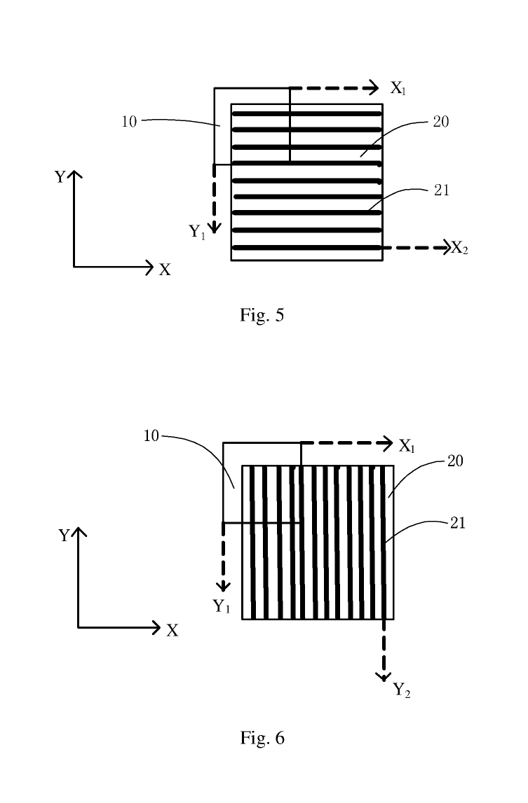

An alternative embodiment of FIG. 5 is shown in FIG. 6, where the extension direction of the electrode strips 21 of the touch control electrode 20 coincides with the direction Y.

To be noted, shape and size of the touch control electrode 20 need not to be the same as the shape and size of the pixel region 10, and they can be determined according to specific circumstances. In a preferable embodiment, the shape of the touch control electrode 20 may be the same as that of the pixel region 10, and each touch control electrode 20 may correspond to one or more pixel regions 10. With such arrangement, sensitivity of the touch panel may be improved.

The touch control electrode 20 may be made of any one of indium tin oxide, indium zinc oxide and indium gallium tin oxide. Of course, other transparent conductive material may be used according to specific circumstances.

The touch panel described in the embodiments of the present disclosure may be an in-cell touch panel or on-cell touch panel. If the touch panel is an in-cell touch panel, the touch sensitive layer is disposed within the display panel; and if the touch panel is an on-cell touch panel, the touch sensitive layer may be disposed at a light exit side of the display panel.

According to another aspect of the present disclosure, there is provided a display device. In an exemplary embodiment, the display device comprises the touch panel according to any of the above described embodiments.

Since the display device utilizes the touch panel according to the embodiments of the present disclosure, almost no Moiré fringe will be generated by the display device during displaying pictures, such that good display effect can be obtained.

The display device may be an electroluminescent display device, such as an electronic paper, a mobile phone, a tablet computer, a television, a display, a notebook computer, a digital picture frame, a navigator or any product or component having a display function.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

What is claimed is:

1. A touch panel, comprising:
a display panel comprising a plurality of pixel regions, each pixel region having a shape of a parallelogram; and
a touch sensitive layer comprising a plurality of touch control electrodes corresponding to the plurality of pixel regions respectively, each touch control electrode comprising a plurality of electrode strips arranged parallel to and spaced apart from each other,
wherein an extension direction of the electrode strips of each touch control electrode is parallel to or perpendicular to a direction of a long side of the parallelogram of a pixel region corresponding to the touch control electrode.

2. The touch panel according to claim 1, wherein the display panel includes an organic electroluminescent diode display panel.

3. The touch panel according to claim 1, wherein the pixel regions and the touch control electrodes have the same shape.

4. The touch panel according to claim 1, wherein the shape of each pixel region is a rhombus or rectangle.

5. The touch panel according to claim 1, wherein a shape of each touch control electrode is a rhombus or rectangle.

6. The touch panel according to claim 1, wherein the pixel regions are arranged into an array.

7. The touch panel according to claim 1, wherein the touch control electrodes are arranged into an array.

8. The touch panel according to claim 1, wherein a material of the touch control electrodes comprises any one of indium tin oxide, indium zinc oxide and indium gallium tin oxide.

9. A display device comprising a touch panel, the touch panel comprising:
a display panel comprising a plurality of pixel regions, each pixel region having a shape of a parallelogram; and
a touch sensitive layer comprising a plurality of touch control electrodes corresponding to the plurality of pixel regions respectively, each touch control electrode comprising a plurality of electrode strips arranged parallel to and spaced apart from each other,
wherein an extension direction of the electrode strips of each touch control electrode is parallel to or perpendicular to a direction of a long side of the parallelogram of a pixel region corresponding to the touch control electrode.

10. The display device according to claim 9, wherein the display panel includes an organic electroluminescent diode display panel.

11. The display device according to claim 9, wherein the pixel regions and the touch control electrodes have the same shape.

12. The display device according to claim 9, wherein the shape of each pixel region is a rhombus or rectangle.

13. The display device according to claim 9, wherein a shape of each touch control electrode is a rhombus or rectangle.

14. The display device according to claim 9, wherein the pixel regions are arranged into an array.

15. The display device according to claim 9, wherein the touch control electrodes are arranged into an array.

16. The display device according to claim 9, wherein a material of the touch control electrodes comprises any one of indium tin oxide, indium zinc oxide and indium gallium tin oxide.
